(19) United States
(12) Patent Application Publication
(10) Pub. No.: US 2020/0105575 A1
(43) Pub. Date: Apr. 2, 2020

(54) METHOD OF FORMING AN RF SILICON ON INSULATOR DEVICE

(71) Applicant: Applied Materials, Inc., Santa Clara, CA (US)

(72) Inventors: Schubert S. CHU, San Francisco, CA (US); Masato ISHII, Sunnyvale, CA (US)

(21) Appl. No.: 16/578,925

(22) Filed: Sep. 23, 2019

Related U.S. Application Data
(60) Provisional application No. 62/739,662, filed on Oct. 1, 2018.

(51) Int. Cl. H01L 21/762

(52) U.S. Cl. CPC H01L 21/7624

(57) ABSTRACT

Embodiments described herein generally provide improved silicon-on-insulator (SOI) substrates for RF integrated circuits and methods for fabricating the same. In one embodiment, a method for forming a multilayer structure is provided. The method includes forming an intrinsic silicon layer on a handle substrate in a process chamber, wherein the handle substrate has a first resistivity and the intrinsic silicon layer having a second resistivity higher than the first resistivity, forming a charge trapping layer on the intrinsic silicon layer in the process chamber, bonding the handle substrate to an active substrate comprising a device layer and an insulating layer, wherein the insulating layer of the active substrate is in physical contact with the charge trapping layer, and removing at least a portion of the handle substrate.

### CROSS-REFERENCE TO RELATED APPLICATIONS

This application claims priority to U.S. Provisional Patent Application No. 62/739,662, filed Oct. 1, 2018, the entirety of which is herein incorporated by reference.

### FIELD

Embodiments of the present disclosure generally relate to a method for producing an improved silicon-on-insulator (SOI) substrates for RF integrated circuits.

### BACKGROUND

Silicon-on-insulator (SOI) substrates are substrates that have a silicon substrate, an insulator layer above the silicon substrate, and a thin layer of active silicon above the insulator layer. SOI substrates have been widely used to facilitate formation of integrated circuits, such as radio frequency (RF) circuits, with faster switching times and lower operating voltages.

However, SOI substrates are generally more expensive than simple bulk semiconductor substrates. Part of the added expense is due to additional processing operations required to produce the SOI substrates before fabrication of the thin layer of active silicon can begin. Therefore, there is a need in the art to provide an improved method for producing SOI substrates.

### SUMMARY

Embodiments described herein generally provide improved silicon-on-insulator (SOI) substrates for RF integrated circuits and methods for fabricating the same. In one embodiment, a method for forming a multilayer structure is provided. The method includes forming an intrinsic silicon layer on a handle substrate in a process chamber, wherein the handle substrate having a first resistivity, and the intrinsic silicon layer having a second resistivity higher than the first resistivity, forming a charge trapping layer on the intrinsic silicon layer in the process chamber, bonding the handle substrate to an active substrate comprising a device layer and an insulating layer, wherein the insulating layer of the active substrate is in physical contact with the charge trapping layer, and removing at least a portion of the handle substrate.

In another embodiment, a multilayer structure is provided. The multilayer structure includes a substrate having a first resistivity, an intrinsic silicon layer disposed on the substrate, wherein the intrinsic silicon has a second resistivity higher than the first resistivity, a charge trapping layer disposed on the intrinsic silicon layer, an insulating layer disposed over the charge trapping layer, and a device layer disposed on the insulating layer, wherein the device layer includes a radio frequency (RF) component.

In another embodiment, a multilayer structure is provided. The multilayer structure includes a silicon substrate having a first resistivity of about 600 Ω-cm or below; an intrinsic silicon layer disposed on the silicon substrate having a second resistivity of about 2×10⁵ Ω-cm or higher, a thickness of about 5 μm to about 250 μm and one or more layers of a semiconductor material selected from a group consisting of silicon, silicon germanium, silicon carbide, and germanium; a charge trapping layer disposed on the intrinsic silicon layer; an insulating layer disposed over the charge trapping layer; and a device layer disposed on the insulating layer, wherein the device layer includes a radio frequency (RF) component.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow chart of a method for manufacturing a silicon-on-insulator (SOI) substrate according to embodiments of the disclosure.

FIGS. 2A to 2D illustrate cross-sectional views of a simplified structure during certain stages of fabrication according to the flow chart of FIG. 1.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

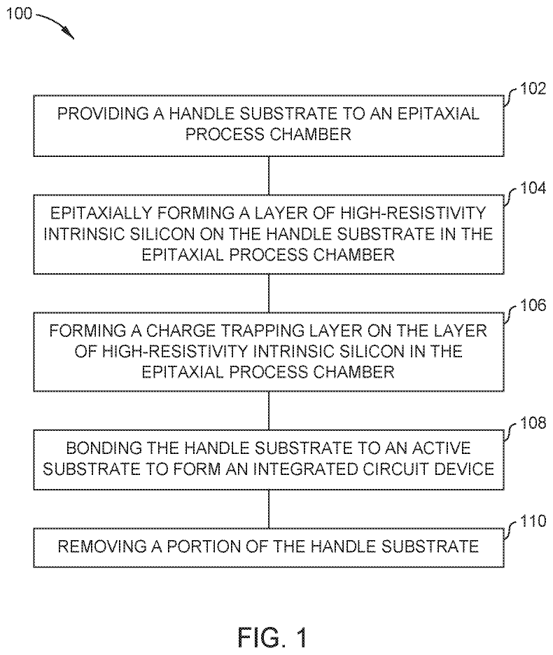

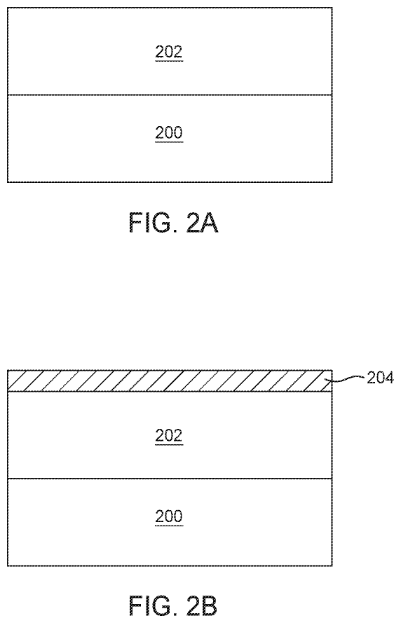

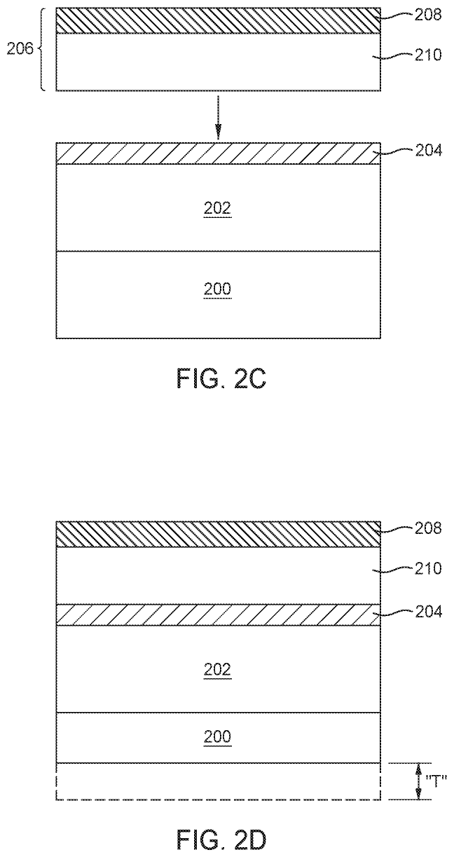

FIG. 1 is a flow chart illustrating an exemplary method for manufacturing a silicon-on-insulator (SOI) substrate according to implementations of the disclosure. FIGS. 2A to 2D illustrate cross-sectional views of a simplified structure during certain stages of fabrication according to the flow chart of FIG. 1. Those skilled in the art will further recognize that the full process for forming a SOI substrate and the associated structures are not illustrated in the drawings or described herein. Instead, for simplicity and clarity, only so much of a process for forming a semiconductor device and the associated structures as is unique to the present disclosure or necessary for an understanding of the present disclosure is depicted and described. In addition, although various operations are illustrated in the drawings and described herein, no limitation regarding the order of such operations or the presence or absence of intervening operations is implied. Operations depicted or described as sequential are, unless explicitly specified, merely done so for purposes of explanation without precluding the possibility that the respective operations are actually performed in concurrent or overlapping manner, at least partially if not entirely

The method 100 begins at block 102 by providing a handle substrate 200 to a process chamber. The handle substrate 200 is to be bonded with an active substrate in a later operation. In one embodiment, the handle substrate 200 is a semiconductor substrate, such as a standard silicon substrate. The term “standard silicon substrate” herein refers to a high purity (e.g., 99% purity or above) monocrystalline silicon formed by a Czochralski growth method. An example Czochralski growth method may include pulling a single seed crystal rod from molten polysilicon to grow a monocrystalline ingot. P-type or N-type impurities may optionally be added to the molten polysilicon to change conductivity type and/or electrical properties (e.g., resistivity) of the handle substrate 200. The monocrystalline ingot is then sliced and polished to form the standard silicon substrate. While silicon substrate is discussed, the handle substrate 200 may be or include other standard semiconductor material, such as a germanium substrate, a silicon germanium (SiGe) substrate, a silicon germanium carbide (SiGeC) substrate, a silicon carbide (SiC) substrate, or a III-V compound substrate, or the like.

The handle substrate 200 can have a diameter of about 150 mm, 200 mm, 300 mm, 400 mm, 450 mm, or larger, and a thickness of about 500 μm or greater. In one embodiment, the handle substrate 200 has a thickness of about 600 μm to about 775 μm. In one example, the handle substrate 200 is a 300 mm silicon substrate that has a standard thickness of about 775 μm and has a (100) or (111) crystal orientation. Depending on the concentration of impurities, the handle substrate 200 can have a resistivity of about 1000 Ω-cm or lower, for example about 600 Ω-cm or below, such as about 0.01 Ω-cm to about 500 Ω-cm. In one embodiment, the handle substrate 200 has a resistivity of about 10 Ω-cm to about 200 Ω-cm.

The process chamber may be any suitable deposition process chamber, such as an epitaxial process chamber, an atomic layer deposition chamber, or a chemical vapor deposition chamber. In one embodiment, the process chamber is an epitaxial process chamber. An exemplary epitaxial process is an Epi CENTURA® chamber that is commercially available from Applied Materials, Inc., of Santa Clara, Calif. Other chambers or tools capable of performing an epitaxy process or CVD-based process processes may also be used to practice embodiments of the present disclosure.

At block 104, a layer of high-resistivity intrinsic silicon 202 is deposited on the handle substrate 200, as shown in FIG. 2A. The layer of high-resistivity intrinsic silicon 202 has a resistivity significantly higher than the handle substrate 200. For example, the layer of high-resistivity intrinsic silicon 202 at room temperature may have a resistivity of about 2×10⁵ Ω-cm or higher, such as about 3×10⁵ Ω-cm or higher. In one embodiment, the layer of high-resistivity intrinsic silicon 202 has a resistivity of about 3.5×10⁵ Ω-cm. Higher resistivity is contemplated depending on the application of an RF semiconductor device. The layer of high-resistivity intrinsic silicon 202 replaces an expensive high resistance handle wafer used by the industry for RF SOI substrates. As a result, the cost of the finished RF SOI substrates can be reduced dramatically.

The layer of high-resistivity intrinsic silicon 202 can be formed on the handle substrate 200 using any suitable deposition method. In one embodiment, the layer of high-resistivity intrinsic silicon 202 is epitaxially grown on the handle substrate 200 by, for example, exposing the handle substrate 200 to a silicon-containing gas, such as a silane-based gas, and a hydrogen-containing gas, such as a hydrogen gas, in the epitaxial process chamber. Suitable silicon-containing gases may include one or more of silanes or halogenated silanes. Silanes may include silane (SiH₄) and higher silanes with the empirical formula SiₓH₍₂ₓ₊₂₎, such as disilane (Si₂H₆), trisilane (Si₃H₈), or tetrasilane (Si₄H₁₀). Halogenated silanes may include compounds with the empirical formula X′_{y}SiₓH_{(2x+2-y)}, where X′=F, Cl, Br or I, such as hexachlorodisilane (Si₂Cl₆), tetrachlorosilane (SiCl₄), dichlorosilane (Cl₂SiH₂) and trichlorosilane (Cl₃SiH). In various embodiments, the layer of high-resistivity intrinsic silicon 202 may have a thickness of about 5 μm to about 250 μm, such as about 5 μm to about 50 μm, or about 50 μm to about 100 μm, or about 50 μm to about 200 μm. In one embodiment, the layer of high-resistivity intrinsic silicon 202 has a thickness of about 25 μm.

At block 106, a charge trapping layer 204 is formed on the layer of high-resistivity intrinsic silicon 202, as shown in FIG. 2B. The charge trapping layer 204 has a high density of electrical charge carriers. The charge trapping layer 204 is configured to reduce the number of surface carriers along the upper regions of the handle substrate 200. The reduction in surface carriers can mitigate formation of accumulation/inversion layers that may occur when voltage bias is applied to RF components within a device layer (e.g., the device layer 208 shown in FIG. 2C) that is subsequently formed over the handle substrate 200, mitigating unwanted RF signal losses.

The charge trapping layer 204 may be one or more layers of a semiconductor material such as silicon, silicon germanium, silicon carbide, or germanium, which may be polycrystalline or amorphous. The charge trapping layer 204 may include dopants such as carbon or germanium. In one embodiment, the charge trapping layer 204 is a polysilicon doped with carbon. The concentration of the dopant (e.g., carbon) in the charge trapping layer 204 may be in a range of about 0.1 mole % to about 30 mole %, for example about 2 mole % to about 5 mole %. In various embodiments, the charge trapping layer 204 may have a thickness of about 5 μm to about 250 μm, such as about 5 μm to about 50 μm, or about 50 μm to about 100 μm, or about 50 μm to about 200 μm. In one embodiment, the charge trapping layer 204 has a thickness of about 25 μm. However, it is contemplated that the charge trapping layer 204 may have other thicknesses, as well, including thicknesses greater and or less than noted above.

The charge trapping layer 204 can be formed on the layer of high-resistivity intrinsic silicon 202 using any suitable deposition method. In one embodiment, the charge trapping layer 204 is grown epitaxially on the layer of high-resistivity intrinsic silicon 202 by, for example, exposing the layer of high-resistivity intrinsic silicon 202 to a silicon-containing gas and a carbon-containing gas in the epitaxial process chamber. Suitable silicon-containing gases may include one or more of silanes. Silanes may include silane (SiH₄) and higher silanes with the empirical formula SiₓH₍₂ₓ₊₂₎, such as disilane (Si₂H₆), trisilane (Si₃H₈), or tetrasilane (Si₄H₁₀). Suitable carbon-containing gases may include one or more of methane, ethane, ethylene, methylsilane, or the like. In one embodiment, the charge trapping layer 204 is formed using silane and methane.

At block 108, the handle substrate 200 is bonded to a donor or active substrate 206 to form an integrated circuit device, as shown in FIG. 2C. The active substrate 206 may include a device layer 208 and an insulating layer 210. The device layer 208 may be a semiconductor layer, such as a silicon layer. In one embodiment, the device layer 208 is a monocrystalline silicon layer. The device layer 208 may be n-doped or p-doped. The device layer 208 may be or include other semiconductor materials, such as germanium, silicon germanium (SiGe), silicon germanium carbide (SiGeC), or any III-V compound material. For RF applications, the device layer 208 can include one or more passive devices and/or radio frequency (RF) components, such as transistors, capacitors, diodes, inductors, and the like.

The insulating layer 210 may be a dielectric layer, such as an oxide layer. Example dielectric layers may include, but are not limited to, silicon dioxide, silicon nitride, silicon oxynitride, hafnium oxide, and any combination thereof. The insulating layer 210 may be formed on the device layer 208 by a high temperature thermal oxidation process.

Once the insulating layer 210 is formed on the device layer 208, the active substrate 206 is inverted and bonded to the handle substrate 200, i.e., the insulating layer 210 is in physical contact with the charge trapping layer 204 of the handle substrate 200. The insulating layer 210 serves as a bonding layer while electrically isolating the device layer 208 from the handle substrate 200. The active substrate 206 and the handle substrate 200 may be subjected to a thermal treatment, such as an anneal process, to solidify the bonding between the active substrate 206 and the handle substrate 200. The thermal treatment may be performed at a temperature of about 200° C. or above, such as about 350° C. or above, for example about 650° C. to about 900° C.

At block 110, a portion of the handle substrate 200 is removed by using any suitable etching or grinding methods. The handle substrate 200 may be ground to a thickness “T” of about 600 μm or less, such as about 200 μm or less, for example about 10 μm to about 100 μm. In some cases, the entire handle substrate 200 can be removed using any physical, mechanical, or chemical means to expose the high-resistivity intrinsic silicon 202. In such a case, the thickness “T” is 0 μm. The removal of the handle substrate 200 enables the active substrate 206 to be provided at a very thin thickness, which allows the RF devices to provide faster switching times and lower operating voltages.

In summary, embodiments of the present disclosure provide improved silicon-on-insulator (SOI) substrates for RF integrated circuits and methods for fabricating the same. The improved RF SOI substrates are formed by epitaxially growing a thin, high-resistivity intrinsic silicon layer on a standard silicon substrate. The improved RF-SOI substrates replace an expensive high resistance handle wafer with an epitaxial silicon layer which dramatically lowers the cost of the finished RF-SOI substrates. In addition, the use of the standard silicon substrate allows the RF SOI substrates to be produced in an easier, faster and more economical manner.

While the foregoing is directed to embodiments of the present disclosure, other and further embodiments of the disclosure may be devised without departing from the basic scope thereof.

1. A method for forming a multilayer structure, comprising:
forming an intrinsic silicon layer on a handle substrate in a process chamber, the handle substrate having a first resistivity, and the intrinsic silicon layer having a second resistivity higher than the first resistivity;
forming a charge trapping layer on the intrinsic silicon layer in the process chamber;
bonding the handle substrate to an active substrate comprising a device layer and an insulating layer, the insulating layer of the active substrate being in physical contact with the charge trapping layer; and
removing at least a portion of the handle substrate.

2. The method of claim 1, wherein the handle substrate is monocrystalline silicon.

3. The method of claim 1, wherein the intrinsic silicon layer is epitaxially grown on the handle substrate.

4. The method of claim 1, wherein the intrinsic silicon layer has a thickness of about 5 μm to about 250 μm.

5. The method of claim 4, wherein the intrinsic silicon layer has a thickness of about 50 μm to about 100 μm

6. The method of claim 1, wherein the first resistivity is about 600 Ω-cm or below.

7. The method of claim 1, wherein the second resistivity is about 2×10⁵ Ω-cm or higher.

8. The method of claim 1, wherein the intrinsic silicon layer is epitaxially grown on the handle substrate by exposing the handle substrate to a silicon-containing gas and a hydrogen-containing gas.

9. The method of claim 1, wherein the charge trapping layer is epitaxially grown on the intrinsic silicon layer by exposing the intrinsic silicon layer to a silicon-containing gas and a carbon-containing gas.

10. The method of claim 1, wherein the handle substrate is subjected to a removal process to have a thickness of about 600 μm or less.

11. The method of claim 1, wherein the handle substrate is removed to expose a portion of the intrinsic silicon layer.

12. The method of claim 1, wherein the device layer comprises a radio frequency (RF) component.

13. A multilayer structure, comprising:
a silicon substrate having a first resistivity;
an intrinsic silicon layer disposed on the silicon substrate, the intrinsic silicon having a second resistivity higher than the first resistivity;
a charge trapping layer disposed on the intrinsic silicon layer;
an insulating layer disposed over the charge trapping layer; and
a device layer disposed on the insulating layer, the device layer comprising a radio frequency (RF) component.

14. The multilayer structure of claim 13, wherein the silicon substrate is monocrystalline silicon.

15. The multilayer structure of claim 13, wherein the first resistivity is about 600 Ω-cm or below.

16. The multilayer structure of claim 13, wherein the second resistivity is about 2×10⁵ Ω-cm or higher.

17. The multilayer structure of claim 13, wherein the intrinsic silicon layer has a thickness of about 5 μm to about 250 μm.

18. The multilayer structure of claim 13, wherein the charge trapping layer comprises one or more layers of a semiconductor material selected from a group consisting of silicon, silicon germanium, silicon carbide, and germanium.

19. The multilayer structure of claim 13, wherein the charge trapping layer is polycrystalline.

20. A multilayer structure, comprising:
a silicon substrate having a first resistivity of about 600 Ω-cm or below;
an intrinsic silicon layer disposed on the silicon substrate, the intrinsic silicon having a second resistivity of about 2×10⁵ Ω-cm or higher, a thickness of about 5 μm to about 250 μm, and including of one or more layers of a semiconductor material selected from a group consisting of silicon, silicon germanium, silicon carbide, and germanium;
a charge trapping layer disposed on the intrinsic silicon layer, the intrinsic silicon layer having;
an insulating layer disposed over the charge trapping layer; and
a device layer disposed on the insulating layer, the device layer comprising a radio frequency (RF) component.
